(19) United States
(12) Patent Application Publication
(10) Pub. No.: US 2025/0357232 A1
(43) Pub. Date: Nov. 20, 2025

(54) SEMICONDUCTOR PACKAGE INCLUDING AN ENCAPSULANT WITH A PERIPHERAL SIDE WALL HAVING A RECESS AND A LEAD DISPOSED IN THE RECESS

(71) Applicant: Infineon Technologies Austria AG, Villach (AT)

(72) Inventors: Edward Fürgut, Dasing (DE); Joon Shyan Tan, Seremban (MY); Lee Shuang Wang, Bukit Baru (MY); Sanjay Kumar Murugan, Melaka (MY)

(21) Appl. No.: 19/210,497

(22) Filed: May 16, 2025

(30) Foreign Application Priority Data
May 18, 2024 (MY) MYPI2024002926
Jul. 30, 2024 (DE) 102024207163.3

(51) Int. Cl. H01L 23/31; H01L 23/00; H01L 23/495

(52) U.S. Cl. CPC H01L 23/3121; H01L 23/49503; H01L 23/49562; H01L 23/49568; H01L 24/48; H01L 24/49; H01L 2224/48091; H01L 2224/48245; H01L 2224/49175; H01L 2924/10272; H01L 2924/1033; H01L 2924/1815

(57) ABSTRACT

A semiconductor package includes an encapsulant having a peripheral side wall with at least one recess therein. The recess has an inner bottom surface and side walls extending between the inner bottom surface and an outer surface of the peripheral side wall of the encapsulant. At least one lead extends from the inner bottom surface into the recess. The lead is spaced from the side walls of the recess.

### TECHNICAL FIELD

The present disclosure relates to a semiconductor package, a method for fabricating the same, a semiconductor device module and a system including a semiconductor package.

### BACKGROUND

Power density is an important driver for the industry. Related with this are performance, dimensions and reliability. The different packaging solutions are manifold and have to address the needs of a specific application.

Over the last couple of years a lot of activities have been carried out concerning the embedding of passive components and active semiconductor dies into printed circuit board PCB or other package carrier systems. Some low voltage use cases have found their way into production as embedding provides additional value compared to module or discrete packaging solutions, such as compactness (power density), short lead lengths, good thermal management and significantly improved power cycling capability. These benefits are also seen to be attractive for power applications with high voltages up to 1200 V and specially for fast switching applications >30 kHz.

Semiconductor chip embedding into a PCB comes along with excellent cooling capacity and very low parasitic inductances due to the short lead lengths. This allows high power density and efficiency in the system design. Especially for fast switching devices such as SiCMOS, GaN, IGBT & diode, CoolMOS & SFET this advantage is used to achieve outstanding performance.

In particular packages with embedded power semiconductor chips may generate a considerable amount of heat during operation. This may limit reliability and performance. Efficiently removing heat from the package may be accomplished by a heat sink or the like. At the same time, electric reliability of a package is required.

For these and other reasons there is a need for the present disclosure.

### SUMMARY

In particular, high voltage applications like electrical vehicles, electric vehicle charging, uninterruptible power supply, etc. require a dedicated design to enable the use in an environment of high electrical fields and high temperatures. The present disclosure for chip embedding offers the solution for such high voltage use cases.

A first aspect of the present disclosure is related to a semiconductor package comprising an encapsulant comprising a peripheral side wall having at least one recess therein, wherein the recess comprises an inner bottom surface and side walls extending between the inner bottom surface and an outer surface of the peripheral side wall of the encapsulant, and wherein at least one lead extends from the inner bottom surface into the recess, the lead being spaced from the side walls of the recess.

A second aspect of the present disclosure is related to a method of manufacturing a semiconductor package, the method comprising providing a leadframe comprising a die pad and a plurality of leads, attaching a semiconductor transistor die to the die pad, applying an encapsulant to the leadframe and the semiconductor transistor die so that the encapsulant comprises a peripheral side wall having at least one recess therein, wherein the side wall comprises an outer surface lateral to the recess, an inner surface at the bottom of the recess, and side walls between the outer surface and the inner surface, wherein applying the encapsulant so that at least one lead of the plurality of extends from the inner bottom surface into the recess, the lead being spaced from the side walls of the recess, and cutting the outer ends of the leads.

A third aspect of the present disclosure is related to a semiconductor device module comprising a package carrier comprising an opening, wherein a semiconductor package according to the first aspect.

A fourth aspect of the present disclosure is related to a semiconductor package comprising an encapsulant comprising a first surface, a second surface opposite the first surface, and an inclined peripheral side wall connecting the first surface and the second surface, wherein the inclined peripheral sidewall comprises corner portions, wherein the corner portions are rounded, preferably with a radius not less than 0.8 mm. This aspect is compatible with all of the aforementioned aspects and all their embodiments. According to an embodiment, the semiconductor package may be any of the semiconductor packages described herein. According to an embodiment, the inclined peripheral sidewall comprises a first inclined portion having a first inclination and a second inclined portion having a second inclination. According to an embodiment, the first portion and the second portion form an apex at the peripheral sidewall. According to an embodiment, an inclination of each of the inclined portions is at most 4°. According to an embodiment, the second inclined portion is larger than the first inclined portion, the apex is closer to the first surface of the encapsulant than to the second surface of the encapsulant, and the second inclined portion is connected to the second surface of the encapsulant. According to an embodiment, the radius of the corner portions is in a range between 0.8 mm and 1.6 mm. According to an embodiment, the encapsulant forms a package body, a thickness of the package body corresponds to a distance between the first surface and the second surface of the encapsulant, and a lateral extension of the package body corresponds to an overall distance between the opposing sidewalls in which the recesses with the leads are arranged, and wherein a ratio between the lateral extension and the thickness of the package body is between 9.0 and 9.5, preferably 9.19.

A fifth aspect of the present disclosure is related to a method of manufacturing a semiconductor package, the method comprising providing a leadframe comprising a die pad and a plurality of leads, attaching a semiconductor transistor die to the die pad, providing an encapsulant to the leadframe and the semiconductor transistor die so that the encapsulant comprises an inclined peripheral side wall, and providing the encapsulant so that the inclined peripheral sidewall comprises corner portions, wherein the corner portions are rounded with a radius not less than 0.8 mm. This aspect is compatible with all of the aforementioned aspects and all their embodiments.

A sixth aspect of the present disclosure is related to a semiconductor package comprising an encapsulant, a leadframe comprising a die pad and a plurality of leads, the die pad having a first main face and a second main face opposite the first main face, wherein the second main face of the die pad is exposed to an outside of the package on a lower surface of the encapsulant, a plurality of via pads, wherein the via pads are exposed on the upper surface of the encapsulant and are otherwise fully embedded in the encapsulant, wherein a ratio of a lateral extension of the second main face of the die pad in a direction between the via pads exposed on the lower surface of the encapsulant and a distance between the via pads at the upper surface of the encapsulant and is at most 0.55. This aspect is compatible with all of the aforementioned aspects and all their embodiments.

A seventh aspect of the present disclosure is related to a system comprising the semiconductor package of any of the preceding aspects (and their embodiments), a core layer having a cavity, in which the semiconductor package is embedded, a first material layer comprising pre-impregnated fibers, covering a lower surface of the core layer and being in contact with the lower surface of the semiconductor package, a second material layer comprising pre-impregnated fibers, covering an upper surface of the core layer opposite the lower surface of the core layer and being in contact with the upper surface of the semiconductor package, wherein the core layer is a printed circuit board, PCB.

Those skilled in the art will recognize additional features and advantages upon reading the following detailed description, and upon viewing the accompanying drawings.

### BRIEF DESCRIPTION OF THE DRAWINGS

The present disclosure is illustrated by way of example, and not by way of limitation, in the figures of the accompanying drawings in which similar reference numerals refer to similar or identical elements. The elements of the drawings are not necessarily to scale relative to each other. The features of the various illustrated examples can be combined unless they exclude each other.

FIG. 1 shows a top view on a semiconductor package and in the marked circles enlarged views of recesses and the leads contained therein.

FIGS. 2A to 2C show a bottom view (FIG. 2A), a bottom perspective view (FIG. 2B), and a top perspective view (FIG. 2C) of the semiconductor package of FIG. 1.

FIG. 3 shows a top view on a leadframe design of the semiconductor package of FIG. 1.

FIG. 4 shows a cross-sectional side view of a semiconductor device module comprising a semiconductor package of FIG. 1.

FIG. 5 shows a further embodiment of the present disclosure from a top-side perspective.

FIG. 6 shows a side view of the embodiment of FIGS. 5 and 6.

FIG. 7 shows the embodiment of FIG. 5 from a bottom-side perspective.

### DETAILED DESCRIPTION

The embodiments described herein are provided as follows.

According to an embodiment of the semiconductor package of the first aspect, none of the leads extends beyond the outer surface of the encapsulant side wall. In particular, an outer surface of the leads is coplanar with or set back from the plane of the outer surface of the encapsulant.

According to an embodiment of the semiconductor package of the first aspect, the semiconductor package comprises a plurality of recesses, each one containing at least one lead, and each one of the recesses and the leads being shaped like the at least one recess and the lead contained therein. It may be provided that a recess contains two or more than two leads. This will be shown in detail in an embodiment below.

According to an embodiment of the semiconductor package of the first aspect, the semiconductor package comprises a plurality of recesses, wherein the recesses are located in opposing side walls of the encapsulant.

According to an embodiment of the semiconductor package of the first aspect, the semiconductor package further comprises a semiconductor transistor die comprising a drain terminal, a source terminal, a gate terminal, and optionally a source/sense terminal. In particular, it may be provided that in a first side wall of the encapsulant, recesses are arranged which comprises leads which are connected with the source terminal (source leads), the gate terminal (gate lead), and the optional source/sense terminal (source/sense lead), and in a second side wall opposite to the first side wall of the encapsulant at least one recess is arranged which comprises at least one lead (drain lead) which is connected with the drain terminal. This will be shown in detail in an embodiment below.

According to an embodiment of the semiconductor package of the first aspect, two source leads are arranged in two different recesses.

According to an embodiment of the semiconductor package of the first aspect, two drain leads are arranged in two different recesses.

According to an embodiment of the semiconductor package of the first aspect, the gate lead and the source/sense lead are arranged in one common recess.

According to an embodiment of the semiconductor package of the first aspect, the semiconductor package further comprises a plurality of via pads wherein the drain leads are connected with a first via pad, the source leads are connected with a second via pad, the gate lead is connected with a third via pad, and the source/sense lead is connected with a fourth via pad. The via pads can be exposed at the upper face of the encapsulant, but otherwise completely embedded in the encapsulant.

According to an embodiment of the semiconductor package of the first aspect, the semiconductor package further comprises a leadframe comprising a die pad and the leads. According to a further embodiment thereof, the semiconductor transistor die is disposed on a first main face of the die pad, wherein a second main face of the die pad opposite to the first main face is exposed to the outside. On the customer side, this can be utilized by applying the semiconductor package to a heat sink for efficient heat dissipation. This will be shown in detail in an embodiment below.

According to an embodiment of the semiconductor package of the first aspect, the semiconductor transistor die comprises one or more of a vertical semiconductor transistor die, a semiconductor power transistor die, an IGBT die, a MOSFET die, a JFET die, a CoolMOS die, a wide band gap semiconductor transistor die, in particular a SiC transistor die or a GaN transistor die.

According to an embodiment of the method of the second aspect, cutting the outer ends of the leads so that none of the leads extends beyond the outer surface of the package side wall. In particular, the cutting may be done so that an outer surface of the leads is coplanar with or set back from the plane of the outer surface of the encapsulant.

According to an embodiment of the method of the second aspect, cutting the outer ends of the leads is performed by one of punching, sawing, or laser cutting.

According to an embodiment of the method of the second aspect, applying the encapsulant is performed so that one main face of the die pad is exposed to the outside.

According to an embodiment of the semiconductor device module of the third aspect, the package carrier is a printed circuit board, in particular comprising a core layer of an FR3 or FR4 material. On both sides of the core layer laminate layers may be applied which fill the spaces between the semiconductor package and the side faces of the opening of the core layer.

According to another embodiment of a method of manufacturing a semiconductor package, the method comprises: providing a leadframe comprising a die pad and a plurality of leads; attaching a semiconductor transistor die to the die pad; applying an encapsulant to the leadframe and the semiconductor transistor die so that the encapsulant comprises a peripheral side wall having at least one recess therein, wherein the sidewall comprises an outer surface lateral to the recess, an inner surface at the bottom of the recess, and side walls between the outer surface and the inner surface, wherein applying the encapsulant so that at least one lead of the plurality of extends from the inner bottom surface into the recess, the lead being spaced from the side walls of the recess; and cutting the outer ends of the leads. According to an embodiment, cutting the outer ends so that none of the leads extends beyond the outer surface of the package sidewall. According to an embodiment aspect, cutting the outer ends so that an external surface of the leads is set back from the plane of the outer surface of the encapsulant. According to an embodiment, cutting the outer ends of the leads by one of punching, sawing, or laser cutting. According to an embodiment, applying the encapsulant so that one main face of the die pad is exposed to the outside.

According to another embodiment of a semiconductor device module, the semiconductor device module comprises: a package carrier comprising an opening; and the semiconductor package disposed in the opening. According to an embodiment, the package carrier is a printed circuit board. According to an embodiment, the semiconductor device module is designed to be inserted into another device.

According to another embodiment of a method of manufacturing a semiconductor package, the method comprises: providing a leadframe comprising a die pad and a plurality of leads; attaching a semiconductor transistor die to the die pad; providing an encapsulant to the leadframe and the semiconductor transistor die such that the encapsulant comprises an inclined peripheral side wall; providing the encapsulant so that the inclined peripheral sidewall comprises corner portions, wherein the corner portions are rounded with a radius not less than 0.8 mm.

According to another embodiment of a semiconductor package, the semiconductor package comprises: an encapsulant; a leadframe comprising a die pad and a plurality of leads, wherein the die pad has a first main face and a second main face opposite the first main face, wherein the second main face of the die pad is exposed to an outside of the package on a lower surface of the encapsulant; and a plurality of via pads exposed on an upper surface of the encapsulant and otherwise fully embedded in the encapsulant, wherein a ratio of a lateral extension of the second main face of the die pad in a direction between the via pads exposed on the lower surface of the encapsulant and a distance between the via pads at the upper surface of the encapsulant and is at most 0.55. According to an embodiment, the exposed second main face of the die pad is configured to be adapted to a heatsink. According to an embodiment, the exposed via pads are configured to be connected to thermal and/or electrical vias. According to an embodiment, the leads, the exposed via pads and the exposed die pad are covered with an adhesion promoter. According to an embodiment, the encapsulant has a surface roughness of at least 5 μm.

According to an embodiment of a system, the system comprises any of the semiconductor packages described herein, a core layer having a cavity in which the semiconductor package is embedded, a first material layer comprising pre-impregnated fibers, covering a lower surface of the core layer and being in contact with the lower surface of the encapsulant, a second material layer comprising pre-impregnated fibers, covering an upper surface of the core layer opposite the lower surface of the core layer and being in contact with the upper surface of the encapsulant, wherein the core layer is a printed circuit board.

In the following detailed description, reference is made to the accompanying drawings, which form a part hereof, and in which is shown by way of illustration specific embodiments in which the disclosure may be practiced. In this regard, directional terminology, such as “top”, “bottom”, “front”, “back”, etc., is used with reference to the orientation of the Figure(s) being described. Because components of embodiments can be positioned in a number of different orientations, the directional terminology is used for purposes of illustration and is in no way limiting. It is to be understood that other embodiments may be utilized and structural or logical changes may be made without departing from the scope of the present disclosure. The following detailed description, therefore, is not to be taken in a limiting sense, and the scope of the present disclosure is defined by the appended claims.

It is to be understood that the features of the various exemplary embodiments described herein may be combined with each other, unless specifically noted otherwise.

As employed in this specification, the terms “bonded”, “attached”, “connected”, “coupled” and/or “electrically connected/electrically coupled” are not meant to mean that the elements or layers must directly be contacted together; intervening elements or layers may be provided between the “bonded”, “attached”, “connected”, “coupled” and/or “electrically connected/electrically coupled” elements, respectively. However, in accordance with the disclosure, the above-mentioned terms may, optionally, also have the specific meaning that the elements or layers are directly contacted together, i.e. that no intervening elements or layers are provided between the “bonded”, “attached”, “connected”, “coupled” and/or “electrically connected/electrically coupled” elements, respectively.

Further, the word “over” used with regard to a part, element or material layer formed or located “over” a surface may be used herein to mean that the part, element or material layer be located (e.g. placed, formed, deposited, etc.) “indirectly on” the implied surface with one or more additional parts, elements or layers being arranged between the implied surface and the part, element or material layer. However, the word “over” used with regard to a part, element or material layer formed or located “over” a surface may, optionally, also have the specific meaning that the part, element or material layer be located (e.g. placed, formed, deposited, etc.) “directly on”, e.g. in direct contact with, the implied surface.

The examples of a semiconductor package may use various types of transistor devices. The examples may use vertical transistor devices wherein those structures may be provided in a form in which at least one electrical contact element is arranged on a first main face of the semiconductor die and at least one other electrical contact element is arranged on a second main face opposite to the main face of the semiconductor die like, for example, MOS transistor structures or IGBT (Insulated Gate Bipolar Transistor) structures.

According to an embodiment of the semiconductor package, the semiconductor transistor die is a semiconductor power transistor die. Here, the term “power semiconductor transistor die” may refer to a semiconductor die providing at least one of high voltage blocking or high current-carrying capabilities. A power semiconductor die may be configured for high currents having a maximum current value of a few Amperes, such as e.g. 10 A, 250 A, 600 A, 1000 A, or a maximum current value of up to or even exceeding 1000 A. Similarly, voltages associated with such current values may have values of a few Volts to a few tens or hundreds or even thousands of Volts, in particular voltage values of 1200V and 1700V/2000V/3.3 kV and higher are of significance.

The examples of a semiconductor package may comprise an encapsulant or encapsulating material having the semiconductor transistor die and the semiconductor driver die embedded therein. The encapsulating material can be any electrically insulating material like, for example, any kind of molding material, any kind of resin material, or any kind of epoxy material. The encapsulating material can also be a polymer material, a polyimide material, a thermoplast material, a silicone material, a ceramic material, and a glass material. The encapsulating material may also comprise any of the above-mentioned materials and further include filler materials embedded therein like, for example, thermally conductive increments like thermally conductive particles like, for example, made of AlO, BNi, AlNi, SiN, diamond, any other thermally conductive particles, or non-thermal conductive fillers, e.g. SiO, SiO2, glass etc.

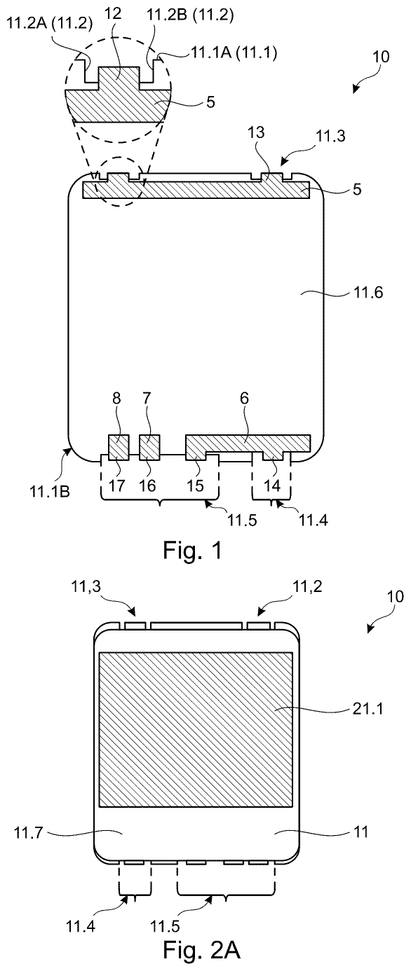

FIG. 1 shows a top view on a semiconductor package and in the marked circles enlarged views of recesses and the leads contained therein.

More specifically, FIG. 1 shows a semiconductor package 10 comprising an encapsulant 11 comprising a peripheral side wall 11.1 comprising therein a plurality of recesses 11.2, 11.3, and 11.4, and 11.5. A first recess 11.2 comprises an inner bottom surface 11.2A and side walls 11.2B extending between the inner bottom surface 11.2A and an outer surface 11.1A of the peripheral side wall 11.1 of the encapsulant 11. A first lead 12 extends from the inner bottom surface 11.2A into the recess 11.2, the first lead 12 being spaced from the side walls 11.2B of the first recess 11.2. The other recesses 11.3, 11.4 and 11.5 are formed in a similar way as the first recess 11.2.

The semiconductor package 10 of the present embodiment comprises a semiconductor transistor die (not shown in FIG. 1), in particular an IGBT die, comprising a source contact, a drain contact, a gate contact, and a source/sense contact. The source contact is connected with source leads, the gate contact is connected with a gate lead, and the source/sense contact is connected with a source/sense lead. The recesses 11.2, 11.3, 11.4, and 11.5 and the respective leads 12 to 17 contained therein are arranged in opposing upper and lower side walls of the encapsulant 11.

The upper side wall as shown in FIG. 1 contains the first recess 11.2 and a second recess 11.3 and respective first and second drain leads 12 and 13 contained therein. The second recess 11.3 and the second drain lead 13 are constructed in an identical way as the first recess 11.2 and the first drain lead 12. The first drain lead 12 and the second drain lead 13 are connected with a first via pad 5. The lower side wall as shown in FIG. 1 contains a third recess 11.4 and a fourth recess 11.5 within the limits of the dotted lines. The third recess 11.4 contains a first source lead 14. The fourth recess 11.5 contains a second source lead 15, a gate lead 16, and a source/sense lead 17. Here a configuration is given in which the source/sense lead 17 is spaced from a left-side side wall of the fourth recess 11.5, the gate lead 16 and the source/sense lead 17 are spaced from each other, and the second source lead 15 is spaced from a right-side side wall of the fourth recess 11.5. The first source lead 14 and the second source lead 15 are connected with a second via pad 6. The gate lead 16 is connected with a third via pad 7, and the source/sense lead 17 is connected with a fourth via pad 8. The via pads 5 to 8 enable contacting by vias. When using the via pads, the number of wires to the via pads can be increased and the main current can flow via the via pads.

It should be noted that in all first to fourth recesses 11.2 to 11.5 outer surfaces of the respective leads 12 to 17 are set back from the plane of the outer surface 11.1A of the encapsulant 11. Alternatively, an outer surface of the leads can also be coplanar with the plane of the outer surface of the encapsulant. Both alternatives are good prerequisites for chip embedding.

In the embodiment shown in FIG. 1 the leads which are connected to the source contact, the gate contact, and the optional source/sense contact may be arranged in the same recess (11.5). Within the recess (11.5) the leads may be evenly distributed. However, the leads may also be unevenly distributed, that is grouped together. For example, the gate contact may be grouped together with the source/sense contact. Both contacts may be spaced apart from the source contact but still be arranged in the same recess.

As will be shown later, the semiconductor transistor die is mounted with its drain contact to a die pad of a leadframe and the die pad is connected with the first and second drain leads 12 and 13.

It should further be noted that the semiconductor package 10 comprises rounded edges, in particular with a radius R=0.25/0.5/1.0/2.0/4.0 mm. This also proves to be advantageous for chip embedding. A reason for the rounding is the milling process of generating the cavity into the core material during the PCB process.

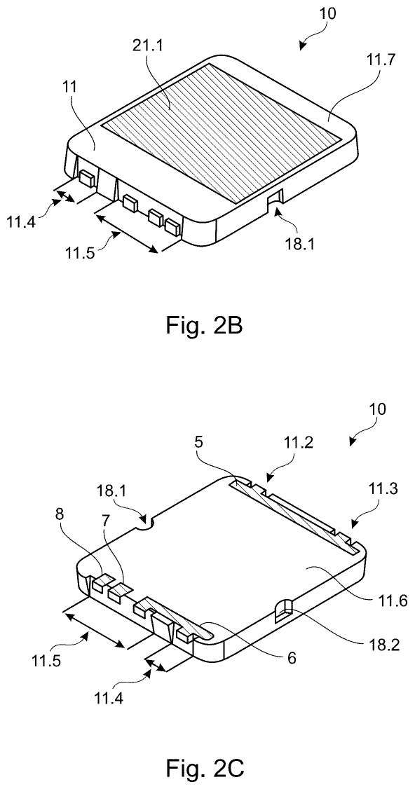

FIGS. 2A to 2C show a bottom view (FIG. 2A), a bottom perspective view (FIG. 2B), and a top perspective view (FIG. 2C) of the semiconductor package of FIG. 1.

More specifically, FIG. 2A shows the rear surface of the die pad 21.1 of the leadframe exposed on the main bottom rear surface of the semiconductor package 10. It allows mounting of a heat sink on the customer's side which will be shown in more detail in FIG. 4. A lowermost edge of the die pad has a significantly large distance to the lowermost edge of the semiconductor package 10 so as to avoid or at least minimize creepage or even short-circuit currents between the source and drain contacts.

FIGS. 2B and 2C serve to illustrate further details of the semiconductor package 10. A possible feature is that the side walls 11.1A of the encapsulant 11 can be beveled to facilitate the insertion of the semiconductor package 10 into the opening of the PCB during the manufacture of the semiconductor module. The beveling is carried out in such a way that the lower side with the drain pad has a slightly smaller area than the upper side with the source pad. As can be seen in FIG. 2B, the beveling results in that the side (walls) surfaces in the recesses 12-17 are triangular in shape. The beveling can also be carried out so that the side (walls) surfaces are trapezoidal or polygonal in shape, as will be further detailed below.

The openings 18.1 and 18.2 are so-called mold ears and result from the molding process and do not need to be explained further here.

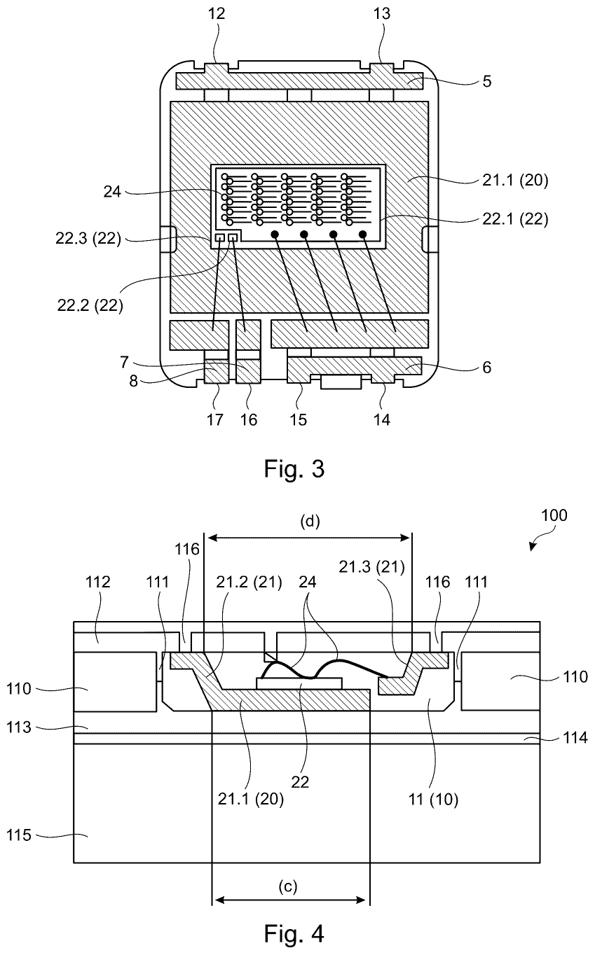

FIG. 3 shows a top view on a leadframe design of the semiconductor package of FIG. 1.

More specifically, FIG. 3 shows the semiconductor package of FIGS. 1 and 2 but this time leaving the encapsulant out thus giving a free view onto the semiconductor transistor die and the leadframe design. The leadframe 20 of the semiconductor package 10 comprises a die pad 21.1 and leads 12 to 17, which correspond to the leads 12 to 17 as shown in FIG. 1. The leads 12 and 13 are connected with the die pad 21.1. A semiconductor transistor die 22 comprises an upper surface with a source pad 22.1, a gate pad 22.2, and a source/sense pad 22.3. A plurality of wire loops 24 connects the source pad 22.1 with an upper metallic layer which is then connected with the source leads 14 and 15. Details thereof are shown in the semiconductor device module as shown in FIG. 4.

It should be noted that instead of the wire loops 24 also other front side connectors can be used. In particular a plurality of metallic posts, for example of copper, can be used to connect the source pad with the upper metallic layer.

The embodiments as described so far have shown a configuration in which the source contact is disposed on an upper main surface and the drain contact on a lower main surface of the semiconductor transistor die. It should be noted that the configuration can also be reversed, with the drain contact on the upper surface and the source contact on the lower surface, an arrangement known as ‘source-down’.

FIG. 4 shows a cross-sectional side view of a semiconductor device module comprising a semiconductor package of FIG. 1.

More specifically, the semiconductor device module 100 as shown in FIG. 4 comprises a printed circuit board (PCB) 110 essentially comprised of a core layer comprising an opening 111, wherein a semiconductor package 10 such as that shown and described in the previous embodiments is disposed in the opening 111. The core layer of the PCB 110 can be made of, for example, an FR 3 or FR 4 material. Instead of a PCB also other types of package carriers could be used.

Also shown in the representation of FIG. 4 are downset sections 21.2 and 21.3 of the leadframe 21 which down-set sections lead from the from the level of the die pad 21.1 and the level of the wire connected source and gate contacts to the via pads 5 to 8 which were shown and described in connection with FIGS. 1 and 2.

The semiconductor device module may further comprise a laminate layer 112 on the upper side of the core layer which, after application, also fills the gaps between the side walls of the semiconductor package 10 and the side walls of the opening 111 of the core layer.

On the customer side, the arrangement consisting of semiconductor package and PCB can be connected to a suitable heat sink 115 via a thermally conductive layer 113, usually a TIM layer (thermal interface layer) and a further metallic layer, in particular made of copper.

The semiconductor device module can further be designed as a power inlay, namely so that it can be inserted into another device and connected with this other device. Such other device can, for example, be a substrate of any kind or a PCB.

FIGS. 1-3 and FIG. 5 show a semiconductor package 10 according to the fourth aspect of disclosure. The semiconductor package 10 comprises an encapsulant 11. The encapsulant 11 comprises a first surface 11.6 and a second surface 11.7. The second surface 11.7 may also be referred to as the rear surface. The first surface 11.6 is arranged opposite to the second surface 11.7. A peripheral sidewall 11.1 of the package may be inclined, that is beveled and may comprise corner portions 11.1B being rounded. A radius of the corner portions 11.1B may be not less than 0.8 mm. A radius of at least 0.8 mm enables the package to be embedded into a recess of a substrate (see also FIG. 4) having rounded corners as well, wherein the rounded corner portions of the recess in the substrate can be obtained by machining with a tool having a radius not less than 0.8 mm. By virtue of the rounded corner portions 11.1B of the package 10, it is easy to insert the semiconductor package 10 into a respectively machined recess in the substrate.

The radius of the corner portions 11.1B may also be in a range between 0.8 mm and 1.6 mm. The larger the radius, the better is the manufacturability of a corresponding recess in the substrate by machining, namely by using a larger machining tool.

It is to be noted that any of the aspects and embodiments described in the following with respect to the attached figures is being conceived and compatible with any of the foregoing aspects and embodiments.

FIG. 6 shows a side view of the embodiments described in relation to the foregoing figures, particularly with FIGS. 1 to 3 and FIG. 5. The peripheral sidewall 11.1, that is, particularly its outer surface 11.1A, has a first inclined portion 501 and a second inclined portion 502. The first inclined portion 501 may have a first inclination and the second inclined portion 502 may have a second inclination different from the first inclination. The first inclined portion 501 and the second inclined portion form an apex 503 at the upper surface 11.1A of the peripheral sidewall 11.1. The apex 503 may be at a parting line, being at 500 μm, which corresponds to a thickness of the leadframe. A cross section of the recess in this embodiment with two inclined portions may be polygonal.

The inclination of the inclined portions 501,502 may be at most 4° with respect to a line normal to the upper surface of the package 10. The encapsulant 11 may form a package body. Keeping the inclination as low as possible may be advantageous to reduce a dead space between the surface of the peripheral side walls of the package body and respective side walls of the recess of a substrate in which the package 10 may be embedded.

The second inclined portion 502 may be larger than the first inclined portion 501. That is, the second inclined portion 502 may have a longer extension along the surface of the peripheral sidewall than the first inclined portion 501. Consequently, the apex 503 may be closer to the first surface 11.6 of the encapsulant 11 than to the second surface 11.7 of the encapsulant 11. The second inclined portion 502 may be connected to the second surface 11.7 and the first inclined portion may be connected to the first surface 11.6. The second inclined portion 502 may be connected to the first inclined portion 501 at the apex 503, which is formed thereby.

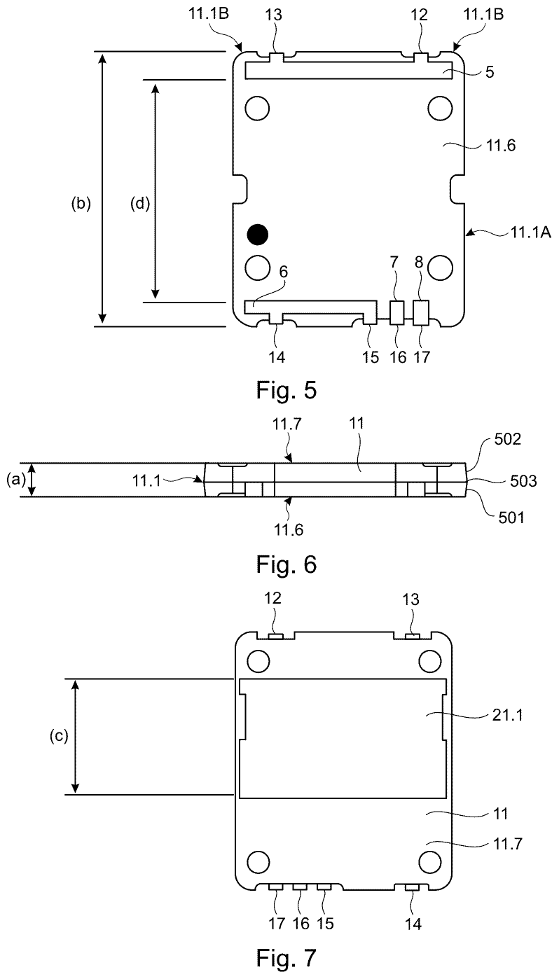

In an embodiment, which is compatible with all of the aforementioned and described embodiments, a thickness (a) of the package body corresponds to a distance between the first surface 11.6 and the second surface 11.7 of the encapsulant, as shown in FIG. 6. A lateral extension (b) of the package body corresponds to an overall distance between parts of the peripheral sidewall, opposite to each other, in which the recesses with the leads are arranged, as shown in FIG. 5. The package body may have a rectangular footprint, having a longer side and shorter side. Usually, the peripheral sidewalls in which the recesses with the leads are arranged are at the shorter sides and spaced apart from each other by the longer sides. Hence the lateral extension as referred to herein may usually refer to the extension of the longer side of the rectangular footprint of the package body.

In an embodiment, the ratio (b)/(a) between the lateral extension (b) and the thickness (a) of the package body is between 9.0 and 9.5. Particularly, the ratio may be 9.19.

FIGS. 1-6 show a semiconductor package manufactured according to the following method, the method comprising: providing a leadframe comprising a die pad and a plurality of leads, attaching a semiconductor transistor die to the die pad, providing an encapsulant to the leadframe and the semiconductor transistor die so that the encapsulant comprises an inclined peripheral side wall, providing the encapsulant so that the inclined peripheral sidewall comprises corner portions, wherein the corner portions are rounded with a radius not less than 0.8 mm.

FIGS. 5, 6 and 7 show an embodiment of the semiconductor package according to the sixth aspect of disclosure. The semiconductor package 10 comprises the encapsulant 11 and the lead frame 20. The leadframe comprises the die pad 21 and a plurality of leads 12-17. The die pad has a first main face and a second main face opposite the first main face. The second main face of the die pad 21 may be exposed to an outside of the package body at a lower surface 11.7 of the encapsulant 11. The semiconductor package may further comprise a plurality of via pads 5,6,7,8. The via pads 5,6,7,8 may be exposed at the upper surface 11.6 of the encapsulant 11 and may otherwise be fully embedded in the encapsulant 11.

A ratio (c)/(d) of a lateral extension (c) of the second main face 21.1 of the die pad in a direction between the via pads exposed on the upper surface 11.6 of the encapsulant and a distance (d) between the via pads at the upper surface 11.6 of the encapsulant may be at most 0.55. This ratio stands for, or may be interpreted as, a measure for the lateral extension of the die pad inside the encapsulant 11. At the aforementioned ratio, the die pad 20 and hence the exposed part of the die pad 21.1 has its maximal lateral extension and hence its maximum ability to transfer heat from the semiconductor chip inside the encapsulant 11 via the die pad to the outside of the package 10. This is also shown in FIG. 4.

The exposed second main face of the die pad 21.1 may be configured to be adapted to a heatsink 115, as exemplary shown in FIG. 4. The heatsink 115 may be any other device capable of receiving heat via the exposed second main face of the die pad 21.1. The heatsink 115 may be adapted for liquid cooling and may be part of an external cooling system. Alternatively, the exposed second main face 21.1 of the die pad 20 may be configured to be attached to thermal vias (not shown).

This may be particularly the case in a configuration wherein the package 10 is embedded in a further substrate 110 and needs to be contacted through further encapsulating upper and/or lower layers.

In an embodiment of the semiconductor package 10 of any preceding embodiment or aspect, the exposed via pads 5,6,7,8 may be configured to be connected to the thermal and/or electrical vias 116 (shown in FIG. 4).

As shown in FIGS. 5, 7, 1, 2C and 3, a lateral dimension of the via pads 5,6,7,8 may be between 0.62 mm and 0.7 mm. In this configuration, it is possible to attach vias in a staggered, that is zig-zag, configuration along the via pads.

The exposed via pads, the leads and the exposed die pad may be covered with an adhesion promoter. Examples for possible adhesion promoters are A2, Acrylics, Chromates, Titanates and Silanes. Using adhesion promoters can significantly improve bonding between the exposed metal surfaces of the package and secondary devices, ensuring a strong and durable bond.

Additionally, to improve bonding strength of the semiconductor package in an embedded state, the mold compound, that is the encapsulant 11, may have a surface roughness of at least 5 μm. An embedded state may be a state wherein the semiconductor package is inserted and sealed inside a substrate, as exemplary shown in FIG. 4. The surface roughness may be in a range between 5 μm and 10 μm.

FIG. 4 shows a cross-sectional side view of a semiconductor device module comprising a semiconductor package of FIGS. 1-3 and 5-7. In addition to the aspects already described, FIG. 4 shows a system which may comprise a semiconductor package 10 of any of the aforementioned embodiments and aspects of the disclosure. The system comprises a core layer 110. The core layer 110 may have a cavity, in which the semiconductor package 10 is embedded. The core layer 110, together with the semiconductor package 10, may be covered by a first material layer 113 comprising pre-impregnated fibres, that is, consisting of a pre-preg material. The first material layer 113 may cover the lower surface of the core layer and be in contact with the lower surface 11.7 of the semiconductor package 10. A second material layer 112 comprising pre-impregnated fibres, may cover an upper surface of the core layer 110. The upper surface of the core layer 110 may be opposite the lower surface of the core layer 110. The second material layer 112, that is the second pre-preg material, may be in contact with the upper surface 11.6 of the semiconductor package 10. The core layer 110 may be a printed circuit board, PCB.

During the embedding process, that is a manufacturing process of the system, the semiconductor package is inserted into the recess of the core layer 110. The lower surface of the core layer 110 and the lower surface of the package is covered with the first material layer 113, that is with the first pre-preg material. The upper surface of the core layer 110 and the upper surface of the package is then covered with the second material layer 112, that is with the second prepreg material. In a pressing step, a pressure may be imposed to the first and the second material layers 113, 112. In this pressing step, resin stored in the pre-impregnated material layers, is pressed out and bleeds into a possible gap between the peripheral sidewalls of the package and the corresponding peripheral sidewalls of the core layer 110, that is the sidewalls of the recess. Thereby, a space between sidewalls of the package and the core layer is filled with resin. By virtue of the slight inclination and the apex of the peripheral side surfaces of the package 10, the dead space, that is the space between sidewalls of the package and the core layer, which is not filled with resin, is reduced. After a possible curing step, vias 116 may be provided through the second material layer 112 to contact the via pads.

In addition, while a particular feature or aspect of an embodiment of the disclosure may have been disclosed with respect to only one of several implementations, such feature or aspect may be combined with one or more other features or aspects of the other implementations as may be desired and advantageous for any given or particular application. Furthermore, to the extent that the terms “include”, “have”, “with”, or other variants thereof are used in either the detailed description or the claims, such terms are intended to be inclusive in a manner similar to the term “comprise”. Furthermore, it should be understood that embodiments of the disclosure may be implemented in discrete circuits, partially integrated circuits or fully integrated circuits or programming means. Also, the term “exemplary” is merely meant as an example, rather than the best or optimal. It is also to be appreciated that features and/or elements depicted herein are illustrated with particular dimensions relative to one another for purposes of simplicity and ease of understanding, and that actual dimensions may differ substantially from that illustrated herein.

Although specific embodiments have been illustrated and described herein, it will be appreciated by those of ordinary skill in the art that a variety of alternate and/or equivalent implementations may be substituted for the specific embodiments shown and described without departing from the scope of the present disclosure. This application is intended to cover any adaptations or variations of the specific embodiments discussed herein. Therefore, it is intended that this disclosure be limited only by the claims and the equivalents thereof.

Although specific examples have been illustrated and described herein, it will be appreciated by those of ordinary skill in the art that a variety of alternate and/or equivalent implementations may be substituted for the specific examples shown and described without departing from the scope of the present invention. This application is intended to cover any adaptations or variations of the specific examples discussed herein. Therefore, it is intended that this invention be limited only by the claims and the equivalents thereof.

It should be noted that the methods and devices including its preferred embodiments as outlined in the present document may be used stand-alone or in combination with the other methods and devices disclosed in this document. In addition, the features outlined in the context of a device are also applicable to a corresponding method, and vice versa. Furthermore, all aspects of the methods and devices outlined in the present document may be arbitrarily combined. In particular, the features of the claims may be combined with one another in an arbitrary manner.

It should be noted that the description and drawings merely illustrate the principles of the proposed methods and systems. Those skilled in the art will be able to implement various arrangements that, although not explicitly described or shown herein, embody the principles of the invention and are included within its spirit and scope. Furthermore, all examples and embodiments outlined in the present document are principally intended expressly to be only for explanatory purposes to help the reader in understanding the principles of the proposed methods and systems. Furthermore, all statements herein providing principles, aspects, and embodiments of the invention, as well as specific examples thereof, are intended to encompass equivalents thereof.

What is claimed is:

1. A semiconductor package, comprising:
an encapsulant comprising a peripheral side wall having at least one recess therein,
wherein the recess comprises an inner bottom surface and a plurality of side walls extending between the inner bottom surface and an outer surface of the peripheral side wall of the encapsulant, and
wherein at least one lead extends from the inner bottom surface into the recess, the lead being spaced from the side walls of the recess.

2. The semiconductor package of claim 1, wherein none of the leads extends beyond the outer surface of the peripheral side wall of the encapsulant.

3. The semiconductor package of claim 1, wherein an outer surface of the leads is coplanar with or set back from a plane of the outer surface of the peripheral side wall of the encapsulant.

4. The semiconductor package of claim 1, further comprising:
a plurality of additional recesses, each additional recess containing at least one additional lead,
wherein each additional recess and each additional lead is shaped like the recess and the lead contained therein, respectively.

5. The semiconductor package of claim 4, wherein the recess and the additional recesses are arranged in opposing side walls of the encapsulant.

6. The semiconductor package of claim 1, further comprising:
a semiconductor transistor die comprising a drain contact;
a source contact; and
a gate contact.

7. The semiconductor package of claim 6, wherein in a first side wall of the encapsulant, a plurality of recesses are arranged which comprise leads that are connected with the source contact and the gate contact, wherein in a second side wall opposite to the first side wall of the encapsulant, at least one recess is arranged which comprises a lead that is connected with the drain contact, and wherein the leads which are connected to the source contact and the gate contact are arranged in the same recess.

8. The semiconductor package of claim 7, further comprising:
a leadframe comprising a die pad and the leads.

9. The semiconductor package of claim 8, wherein the semiconductor transistor die is disposed on a first main face of the die pad, and wherein a second main face of the die pad opposite to the first main face is exposed to the outside.

10. The semiconductor package of claim 6, wherein the semiconductor transistor die comprises one or more of a vertical semiconductor transistor die, a semiconductor power transistor die, an IGBT die, a MOSFET die, a JFET die, a CoolMOS die, a wide band gap semiconductor transistor die, in particular a SiC transistor die or a GaN transistor die.

11. The semiconductor package of claim 1, further comprising:
a plurality of via pads;
a plurality of drain leads connected with a first via pad of the plurality of via pads,
a plurality of source leads connected with a second via pad of the plurality of via pads,
a gate lead connected with a third via pad of the plurality of via pads; and
a plurality of source/sense leads connected with a fourth via pad of the plurality of via pads.

12. The semiconductor package of claim 11, wherein the via pads are exposed on an upper face of the encapsulant and otherwise fully embedded in the encapsulant.

13. A system, comprising:
the semiconductor package of claim 1;
a core layer having a cavity in which the semiconductor package is embedded;
a first material layer comprising pre-impregnated fibers, covering a lower surface of the core layer and being in contact with the lower surface of the encapsulant;
a second material layer comprising pre-impregnated fibers, covering an upper surface of the core layer opposite the lower surface of the core layer and being in contact with the upper surface of the encapsulant, wherein the core layer is a printed circuit board.

14. A semiconductor package, comprising:
an encapsulant comprising a first surface, a second surface opposite the first surface, and an inclined peripheral side wall connecting the first surface and the second surface,
wherein the inclined peripheral sidewall comprises corner portions,
wherein the corner portions are rounded.

15. The semiconductor package of claim 14, wherein the inclined peripheral sidewall comprises a first inclined portion having a first inclination and a second inclined portion having a second inclination.

16. The semiconductor package of claim 15, wherein an inclination of each of the inclined portions is at most 4°.

17. The semiconductor package of claim 15, wherein the first inclined portion and the second inclined portion form an apex at the peripheral sidewall.

18. The semiconductor package of claim 17, wherein the second inclined portion is larger than the first inclined portion, wherein the apex is closer to the first surface of the encapsulant than to the second surface of the encapsulant, and wherein the second inclined portion is connected to the second surface of the encapsulant.

19. The semiconductor package of claim 14, wherein a radius of the corner portions is in a range between 0.8 mm and 1.6 mm.

20. The semiconductor package of claim 14, wherein the encapsulant forms a package body, wherein a thickness of the package body corresponds to a distance between the first surface and the second surface of the encapsulant, wherein a lateral extension of the package body corresponds to an overall distance between the opposing sidewalls in which recesses with leads are arranged, and wherein a ratio between the lateral extension and the thickness of the package body is between 9.0 and 9.5.

21. A semiconductor package, comprising:
an encapsulant;
a leadframe comprising a die pad and a plurality of leads, wherein the die pad has a first main face and a second main face opposite the first main face, wherein the second main face of the die pad is exposed to an outside of the package on a lower surface of the encapsulant; and
a plurality of via pads exposed on an upper surface of the encapsulant and otherwise fully embedded in the encapsulant,
wherein a ratio of a lateral extension of the second main face of the die pad in a direction between the via pads exposed on the lower surface of the encapsulant and a distance between the via pads at the upper surface of the encapsulant and is at most 0.55.

22. The semiconductor package of claim 21, wherein the exposed second main face of the die pad is configured to be adapted to a heatsink.

23. The semiconductor package of claim 21, wherein the exposed via pads are configured to be connected to thermal and/or electrical vias.

24. The semiconductor package of claim 21, wherein the leads, the exposed via pads and the exposed die pad are covered with an adhesion promoter.

25. The semiconductor package of claim 21, wherein the encapsulant has a surface roughness of at least 5 μm.
